(19) United States
(12) Patent Application Publication
(10) Pub. No.: US 2020/0176284 A1
(43) Pub. Date: Jun. 4, 2020

(54) LASER IRRADIATION DEVICE, METHOD OF MANUFACTURING THIN FILM TRANSISTOR, AND PROJECTION MASK

(71) Applicant: V Technology Co., Ltd., Yokohama (JP)

(72) Inventors: Michinobu Mizumura, Yokohama (JP); Makoto Hatanaka, Yokohama (JP); Toshinari Arai, Yokohama (JP)

(21) Appl. No.: 16/787,855

(22) Filed: Feb. 11, 2020

Related U.S. Application Data
(63) Continuation of application No. PCT/JP2018/028351, filed on Jul. 27, 2018.

(30) Foreign Application Priority Data
Aug. 15, 2017 (JP) 2017-156969

(51) Int. Cl. H01L 21/67; H01L 21/268; H01L 27/12; H01L 29/786; H01L 29/66

(52) U.S. Cl. CPC H01L 21/67115; H01L 21/268; H01L 29/6675; H01L 29/78672; H01L 27/1285

(57) ABSTRACT

A laser irradiation device is provided with a light source that generates a laser beam, a projection lens that irradiates a prescribed region of an amorphous silicon thin film deposited on a substrate with the laser beam, and a projection mask pattern that is disposed on the projection lens and provided with a plurality of opening portions such that the prescribed region of the amorphous silicon thin film is irradiated with the laser beam; wherein the projection lens irradiates the prescribed region of the amorphous silicon thin film on the substrate moving in a prescribed direction with the laser beam through the projection mask pattern and the areas of at least neighboring opening portions in the projection mask pattern differ from each other in one row orthogonal to the movement direction.

### TECHNICAL FIELD

This disclosure relates to forming of a thin film transistor, and more particularly to a laser irradiation device that irradiates an amorphous silicon thin film with a laser beam to form a polysilicon thin film, a method of manufacturing a thin film transistor, and a projection mask.

### BACKGROUND

As an inverted staggered thin film transistor, there is one in which an amorphous silicon thin film is used for a channel region. However, since an amorphous silicon thin film has a low electron mobility, there is a problem that mobility of electric charge in a thin film transistor is reduced when an amorphous silicon thin film is used for a channel region.

Therefore, there is a technique in which a prescribed region of an amorphous silicon thin film is poly-crystallized by being instantaneously heated by a laser beam to form a polysilicon thin film having a high electron mobility and the polysilicon thin film is used as a channel region.

For example, Japanese Unexamined Patent Application Publication No. 2016-100537 discloses that an amorphous silicon thin film is formed on a substrate, and then the amorphous silicon thin film is irradiated with a laser beam such as an excimer laser to be laser-annealed, thereby performing a process of melting and solidifying the amorphous silicon thin film in a short time to crystallize it into a polysilicon thin film. Japanese Unexamined Patent Application Publication No. 2016-100537 discloses that, by performing the process, a channel region between a source and a drain of a thin film transistor can be formed by a polysilicon thin film having a high electron mobility, and thus a response time of a transistor can be reduced.

In the thin film transistor disclosed in Japanese Unexamined Patent Application Publication No. 2016-100537, a channel region between a source and a drain is formed by (one) polysilicon thin film at one place. For that reason, characteristics of the thin film transistor depend on the (one) polysilicon thin film at one place.

Since a variation occurs in an energy density of the laser beam such as an excimer laser for each irradiation (shot), a variation also occurs in electron mobility of the polysilicon thin film formed using the laser beam. For that reason, characteristics of the thin film transistor formed using the polysilicon thin film also depend on the variation in the energy density of the laser beam.

As a result, there is a possibility that a variation may occur in the characteristics of the plurality of thin film transistors included in the substrate.

It could therefore be helpful to provide a laser irradiation device in which variations in characteristics of a plurality of thin film transistors included in a substrate can be inhibited, a method of manufacturing a thin film transistor, and a projection mask.

### SUMMARY

We thus provide:

A laser irradiation device may include a light source that generates a laser beam, a projection lens that irradiates a prescribed region of an amorphous silicon thin film deposited on a substrate with the laser beam, and a projection mask pattern disposed on the suitable position over the projection lens and provided with a plurality of opening portions to irradiate the prescribed region of the amorphous silicon thin film with the laser beam, and is characterized in that the projection lens irradiates the prescribed region of the amorphous silicon thin film on the substrate moving in a prescribed direction with the laser beam through the projection mask pattern, and the projection mask pattern is configured such that areas of at least neighboring opening portions in a column orthogonal to the movement direction are different from each other.

The laser irradiation device may be characterized in that the projection lens is a plurality of microlenses included in a microlens array that can separate the laser beam, and the projection mask pattern is configured such that the areas of at least the neighboring opening portions among the opening portions corresponding to one column of the microlenses orthogonal to the movement direction are different from each other.

The laser irradiation device may be characterized in that the laser beam radiated from the light source is radiated to the prescribed region of the amorphous silicon thin film through the microlenses corresponding to the one column orthogonal thereto in a single irradiation, and the projection lens irradiates at least neighboring prescribed regions among prescribed regions of the amorphous silicon thin film included in the column orthogonal to the movement direction with the laser beam in different irradiation ranges.

The laser irradiation device may be characterized in that the projection mask pattern is configured such that a total area of the plurality of opening portions corresponding to the microlenses corresponding to one row in the movement direction is set to a prescribed value.

The laser irradiation device may be characterized in that the projection mask pattern is configured such that the areas of at least the neighboring opening portions among the opening portions corresponding to one row of the microlenses in the movement direction are different from each other.

The laser irradiation device may be characterized in that the projection lens radiates the laser beam to the amorphous silicon thin film attached to a region corresponding to a region between a source electrode and a drain electrode included in a thin film transistor to form a polysilicon thin film.

A method of manufacturing a thin film transistor may include a first step of generating a laser beam, a second step of irradiating a prescribed region of an amorphous silicon thin film deposited on a substrate with the laser beam using a projection lens provided with a projection mask pattern including a plurality of opening portions, and a third step of moving the substrate in a prescribed direction each time the laser beam is radiated, and is characterized in that, in the second step, the laser beam is radiated via the projection mask pattern in which areas of at least neighboring opening portions in one column orthogonal to the movement direction are different from each other.

The method may be characterized in that the projection lens is a plurality of microlenses included in a microlens array that can separate the laser beam and, in the second step, the laser beam is radiated through the projection mask pattern in which the areas of at least the neighboring opening portions corresponding to the microlenses in the one column orthogonal to the movement direction are different from each other.

The method may be characterized in that the laser beam radiated from the light source is radiated to the prescribed region of the amorphous silicon thin film through microlenses corresponding to the one column orthogonal thereto in a single irradiation and, in the second step, the laser beam is radiated to at least neighboring prescribed regions of the amorphous silicon thin film among prescribed regions of the amorphous silicon thin film included in the column orthogonal to the movement direction with the laser beam in different irradiation ranges.

The method may be characterized in that the prescribed region of the amorphous silicon thin film is irradiated with the laser beam via the projection mask pattern in which, in the second step, a total area of the plurality of opening portions corresponding to the microlenses corresponding to one row in the movement direction is set to a prescribed value.

The method may be characterized in that the prescribed region of the amorphous silicon thin film is irradiated with the laser beam via the projection mask pattern in which, in the second step, areas of at least neighboring opening portions among the opening portions corresponding to the microlenses in one row in the movement direction are different from each other.

The method may be characterized in that, in the second step, the prescribed region of the amorphous silicon thin film deposited on a region corresponding to a region between a source electrode and a drain electrode included in the thin film transistor is irradiated with the laser beam to form a polysilicon thin film.

A projection mask is disposed on a projection lens that radiates a laser beam generated from a light source, and is provided with a plurality of opening portions to irradiate a prescribed region of an amorphous silicon thin film deposited on a substrate moving in a prescribed direction with the laser beam, and each of the plurality of opening portions is configured such that areas of at least neighboring opening portions in one column orthogonal to the prescribed direction are different from each other.

A laser irradiation device, a method of manufacturing a thin film transistor, and a projection mask, in which variations in characteristics of a plurality of thin film transistors included in a substrate can be inhibited are provided.

### BRIEF DESCRIPTION OF THE DRAWINGS

FIG. 1 is a diagram showing a configurational example of a laser irradiation device 10.

FIG. 2 is a diagram showing a configurational example of a microlens array 13.

FIG. 3 is a schematic diagram showing an example of a thin film transistor 20 of which a prescribed region has been annealed.

FIG. 4 is a schematic diagram showing an example of a substrate 30 that the laser irradiation device 10 irradiates with a laser beam 14.

FIGS. 5A and 5B are schematic diagrams showing another example of the substrate 30 that the laser irradiation device 10 irradiates with the laser beam 14.

FIG. 6 is a schematic diagram showing a configurational example of a projection mask pattern 15 provided on a microlens array 13.

FIG. 7 is a schematic diagram showing another configurational example of the projection mask pattern 15 provided on the microlens array 13.

FIG. 8 is a diagram showing another configurational example of the laser irradiation device 10.

### DESCRIPTION OF REFERENCES

10 Laser irradiation device
11 Laser light source
12 Coupling optical system
13 Microlens array
14 Laser beam
15 Projection mask pattern
16 Opening portion (transmission region)
17 Microlens
18 Projection lens
20 Thin film transistor
21 Amorphous silicon thin film
22 Polysilicon thin film
23 Source
24 Drain
30 Substrate

### DETAILED DESCRIPTION

Hereinafter, examples will be specifically described with reference to the accompanying drawings.

### FIRST EXAMPLE

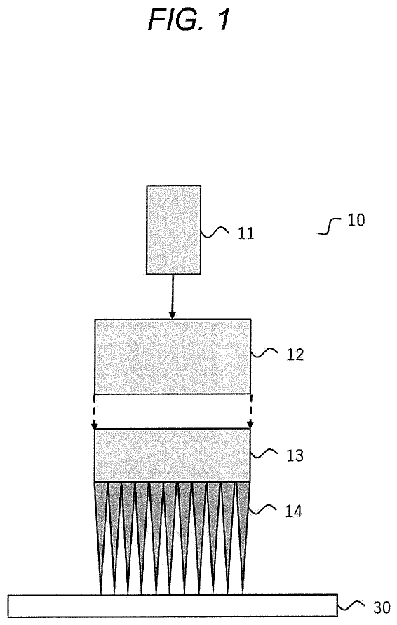

FIG. 1 is a diagram showing a configuration of a laser irradiation device 10 according to a first example.

The laser irradiation device 10 according to the first example is, for example, a device that laser irradiates (anneals) and recrystallizes a reserved channel-region with a laser beam 14, in a process of manufacturing a semiconductor device such as a thin film transistor (TFT) 20.

The laser irradiation device 10 is used, for example, when forming a thin film transistor of a pixel such as a peripheral circuit of a liquid crystal display device. In forming such a thin film transistor, first, a gate electrode made of a metal film such as Al is formed in a pattern on a substrate 30 by sputtering. Then, a gate insulating film made of a SiN film is formed on the entire surface of the substrate 30 using a low-temperature plasma chemical vapor deposition (CVD) method. Thereafter, an amorphous silicon thin film 21 is formed on the gate insulating film by, for example, a plasma CVD method. That is, the amorphous silicon thin film 21 is formed (deposited) on the entire surface of the substrate 30. Finally, a silicon dioxide (SiO₂) film is formed on the amorphous silicon thin film 21. Then, a prescribed region (a region that becomes the channel region in the thin film transistor 20) of the amorphous silicon thin film 21 on the gate electrode is irradiated and annealed with the laser beam 14 using the laser irradiation device 10 illustrated in FIG. 1 so that the prescribed region is poly-crystallized into polysilicon. Also, although the substrate 30 is, for example, a glass substrate, the substrate 30 may not be necessarily made of a glass material and may be a substrate of any material such as a resin substrate formed of a material such as a resin.

As shown in FIG. 1, in the laser irradiation device 10, a beam system of the laser beam 14 emitted from a laser light source 11 is expanded by a coupling optical system 12, and a luminance distribution thereof is made uniform. The laser light source 11 is, for example, an excimer laser that emits the laser beam 14 having a wavelength such as 308 nm and 248 nm at a prescribed repetition cycle.

Then, the laser beam 14 is separated into a plurality of laser beams 14 by a plurality of opening portions (transmission regions) of a projection mask pattern 15 (not shown) provided on a microlens array 13 to be radiated to the prescribed region of the amorphous silicon thin film 21. The projection mask pattern 15 is provided on the microlens array 13, and the prescribed region is irradiated with the laser beam 14 using the projection mask pattern 15. Then, the prescribed region of the amorphous silicon thin film 21 is instantaneously heated and melted, and a part of the amorphous silicon thin film 21 becomes a polysilicon thin film 22. Also, the projection mask pattern 15 may be called a projection mask.

The polysilicon thin film 22 has an electron mobility higher than that of the amorphous silicon thin film 21 and is used as a channel region to electrically connect a source 23 and a drain 24 in a thin film transistor 20. Also, in the example of FIG. 1, although an example in which the microlens array 13 is used has been shown, the microlens array 13 may not necessarily be used and the laser beam 14 may be radiated using one projection lens. Further, in the first example, a configuration in which the polysilicon thin film 22 is formed using the microlens array 13 will be described as an example.

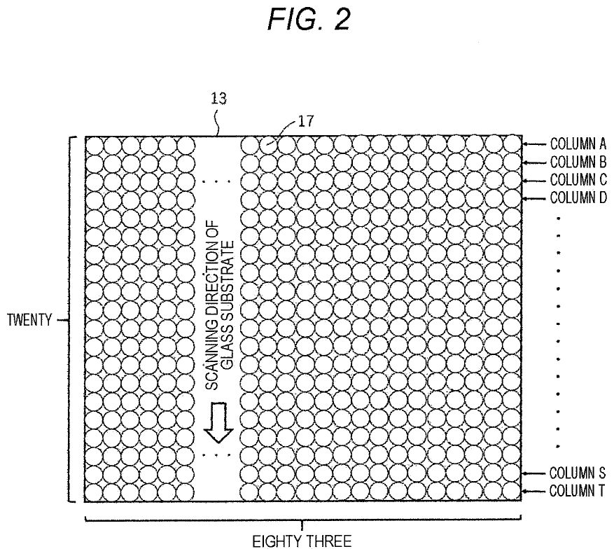

FIG. 2 is a diagram showing a configuration of the microlens array 13 used for the annealing process. In the microlens array 13, twenty microlenses 17 are disposed in one column (or one row) in a scanning direction. The laser irradiation device 1 irradiates the prescribed region of the amorphous silicon thin film 21 with the laser beam 14 using at least some of the twenty microlenses 17 included in one column (or one row) of the microlens array 13. Also, the number of microlenses 17 in one column (or one row) included in the microlens array 13 is not limited to twenty and may be any number.

As shown in FIG. 2, the microlens array 13 includes twenty microlenses 17 in one column (or one row) and includes, for example, eighty-three microlenses in one row (or one column). Also, eighty-three is merely an example and the number of the microlenses may be any number.

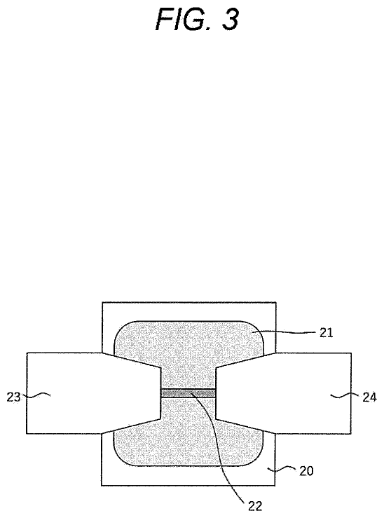

FIG. 3 is a schematic diagram showing an example of the thin film transistor 20 in which the prescribed region has been annealed. Also, the thin film transistor 20 is formed by first forming the polysilicon thin film 22 and then forming the source 23 and the drain 24 at both ends of the formed polysilicon thin film 22.

As shown in FIG. 3, the thin film transistor 20 has the polysilicon thin film 22 formed between the source 23 and the drain 24. The laser irradiation device 10 irradiates the prescribed region of the amorphous silicon thin film 21 with the laser beam 14 using, for example, twenty microlenses 17 included in one column (or one row) of the microlens array 13. That is, the laser irradiation device 10 irradiates the prescribed region of the amorphous silicon thin film 21 with twenty shots of the laser beam 14. As a result, the prescribed region of the amorphous silicon thin film 21 is instantaneously heated and melted in the region that becomes the thin film transistor 20, and is formed into the polysilicon thin film 22.

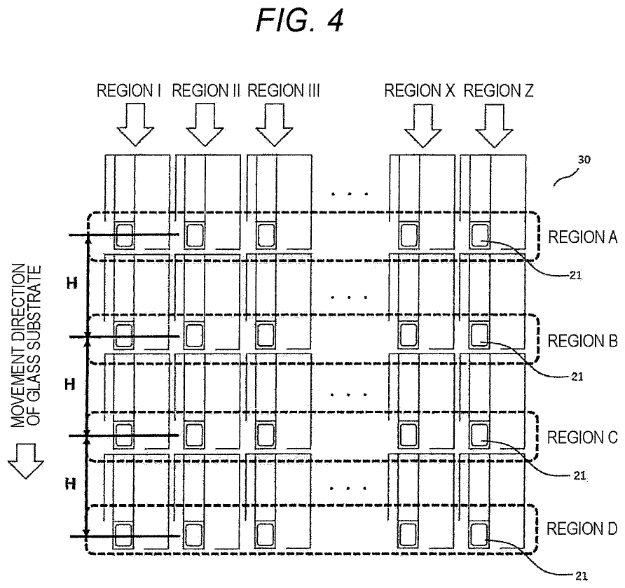

FIG. 4 is a schematic diagram showing an example of the substrate 30 that the laser irradiation device 10 irradiates with the laser beam 14. Also, the substrate 30 may not necessarily be a glass material and may be a substrate of any material such as a resin substrate formed of a material such as a resin. The substrate 30 includes a plurality of pixels 31, and each of the pixels 31 includes the thin film transistor 20. The thin film transistor 20 performs light transmission control in each of the plurality of pixels 31 by electrically turning on/off. In addition, the amorphous silicon thin film 21 is provided on the entire surface of the substrate 30. The prescribed region of the amorphous silicon thin film 21 is a portion that becomes the channel region of the thin film transistor 20.

The laser irradiation device 10 irradiates the prescribed region (the region that becomes the channel region in the thin film transistor 20) of the amorphous silicon thin film 21 with the laser beam 14. The laser irradiation device 10 radiates the laser beam 14 at a prescribed cycle, moves the substrate 30 while the laser beam 14 is not radiated, and then irradiates a prescribed region of the next amorphous silicon thin film 21 with the laser beam 14. As shown in FIG. 3, the amorphous silicon thin film 21 is disposed on the entire surface of the substrate 30. Then, the laser irradiation device 10 irradiates the prescribed region of the amorphous silicon thin film 21 disposed on the substrate 30 with the laser beam 14 at a prescribed cycle.

Further, the laser irradiation device 10 irradiates the prescribed region of the amorphous silicon thin film 21 on the substrate with the laser beam 14 using the microlens array 13. The laser irradiation device 10 radiates, for example, the laser beam 14 to a region A shown in FIG. 4 in the amorphous silicon thin film 21 provided (deposited) on the entire surface of the substrate 30. Also, the laser irradiation device 10 also radiates the laser beam 14 to a region B shown in FIG. 4 in the amorphous silicon thin film 21 provided (deposited) on the entire surface of the substrate 30.

The laser irradiation device 10 irradiating the laser beam 14 using each of the twenty microlenses 17 included in one column (or one row) of the microlens array 13 shown in FIG. 2 to perform the annealing process is considered.

In this example, first, a region A in FIG. 4 of the amorphous silicon thin film 21 provided (deposited) on the entire surface of the substrate 30 is irradiated with the laser beam 14 using first microlenses 17a included in the microlens array 13 shown in FIG. 2. Thereafter, the substrate 30 is moved by a prescribed interval “H.” While the substrate 30 is moving, the laser irradiation device 10 may stop radiation of the laser beam 14. Then, after the substrate 30 is moved by the interval “H,” a region A in FIG. 4 of the amorphous silicon thin film 21 is irradiated with the laser beam 14 using second microlenses 17b included in the microlens array 13 shown in FIG. 2. Also, the laser irradiation device 10 may stop radiation of the laser beam 14 when the substrate 30 is moving and may irradiate the substrate 30 that is moving with the laser beam 14.

An irradiation head of the laser irradiation device 10 (that is, the laser light source 11, the coupling optical system 12, the microlens array 13, and the projection mask pattern 15) may move with respect to the substrate 30.

The laser irradiation device 10 repeats the above steps and finally irradiates the region A in FIG. 4 of the amorphous silicon thin film 21 with the laser beam 14 using microlenses 17t (that is, the last microlenses 17) of the microlens array 13 shown in FIG. 2. As a result, the region A of the amorphous silicon thin film 21 is irradiated with the laser beam 14 using each of the twenty microlenses 17 included in one column (or one row) of the microlens array 13 shown in FIG. 2.

In the same manner, the laser irradiation device 10 also irradiates the region B in FIG. 4 of the amorphous silicon thin film 21 with the laser beam 14 using each of the twenty microlenses 17 included in one column (or one row) of the microlens array 13 shown in FIG. 2. However, since a position of the region B is different from that of the region A by the interval “H” in the movement direction of the substrate, a timing of radiating the laser beam 14 is delayed by one irradiation. That is, when the region A is irradiated with the laser beam 14 using the second microlenses 17b, the region B is irradiated with the laser beam 14 using the first microlenses 17a. Then, when the region A is irradiated with the laser beam 14 using the twentieth microlenses 17t (that is, the last microlenses 17), the region B is irradiated with the laser beam using the previous nineteenth microlenses 17s. Then, the region B is irradiated with the laser beam using the twentieth microlenses 17t (that is, the last microlenses 17) at the timing of the next laser beam irradiation.

That is, the region A and the region B in FIG. 4 of the amorphous silicon thin film 21 are different from each other in the lastly radiated laser beam 14.

In an excimer laser, stability between pulses is about 0.5%. That is, the laser irradiation device 10 causes a variation of about 0.5% in an energy density of the laser beam 14 for each shot. For that reason, there is a possibility that a variation may occur in the electron mobility of the polysilicon thin film 22 formed by the laser irradiation device 10. In addition, the electron mobility of the polysilicon thin film 22 formed by radiating the laser beam 14 depends on an energy density of the laser beam 14 finally radiated to the polysilicon thin film 22, that is, an energy density of the last shot.

For that reason, since the region A and the region B in prescribed regions of the amorphous silicon thin film 21 are different from each other in the lastly radiated laser beam, electron mobilities of the formed polysilicon thin films 22 are different from each other.

On the other hand, since the lastly radiated laser beam 14 is the same in the region A of the prescribed regions of the amorphous silicon thin film 21, electron mobilities of the formed polysilicon thin films 22 are the same in the region A. This is also the same between prescribed regions of the amorphous silicon thin film 21 included in the region B, and electron mobilities of the formed polysilicon thin films 22 are the same in the region B. That is, although regions adjacent to each other on the substrate have different electron mobilities, prescribed regions of the amorphous silicon thin film 21 in the same region have the same electron mobility.

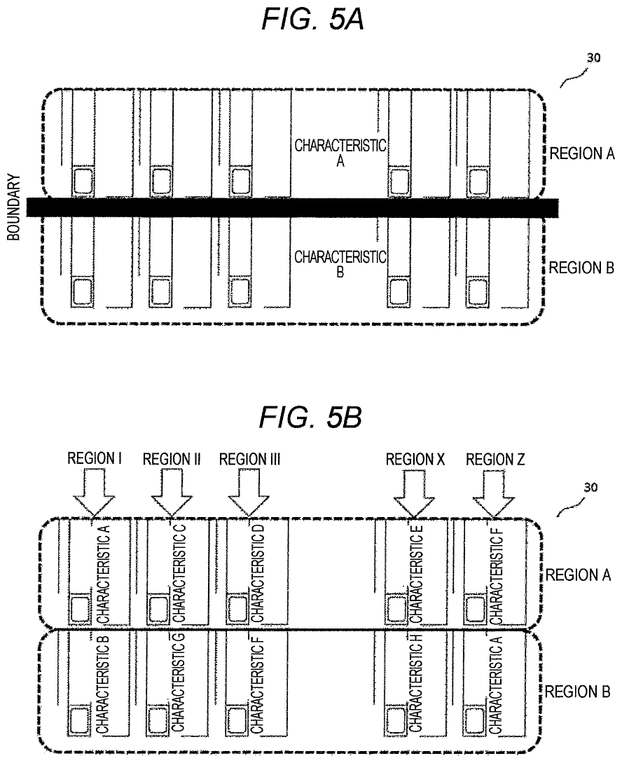

This causes display unevenness on a liquid crystal screen. As illustrated in FIG. 5A, since a boundary between the region A and the region B has a “line shape,” thin film transistors 20 having different characteristics abut each other at the “linear” boundary, and differences in display (for example, differences in shades of color or the like) resulting from differences in characteristics appear as a “line.” As a result, the display unevenness on the liquid crystal screen becomes “streaks,” that are emphasized at a non-negligible level.

Therefore, in the first example, at least prescribed regions of neighboring amorphous silicon thin films 21 among prescribed regions of a plurality of amorphous silicon thin films 21 included in the same region (for example, the region A) shown in FIG. 4 are irradiated with the laser beam 14 in different irradiation ranges. As a result, the irradiation ranges of the laser beam 14 radiated to the prescribed regions of the neighboring amorphous silicon thin films 21 in the same region (for example, in the region A) are different from each other. As a result, electron mobilities of neighboring polysilicon thin films 22 in the same region (for example, in the region A) are different from each other. This also causes characteristics of neighboring thin film transistors 20 in the same region (for example, in the region A) to be different from each other. In this example, the characteristics of the thin film transistors 20 adjacent to each other in the entire substrate 30 are different from each other, and thus differences in display (for example, differences in shades of color or the like) due to differences in characteristics do not appear as a “line shape.” For that reason, the display unevenness does not become “streaks” on the liquid crystal screen, and the display unevenness can be prevented from being emphasized.

FIGS. 5A and 5B are diagrams explaining whether or not display unevenness occurs due to the neighboring thin film transistors 20 on the substrate 30. In FIG. 5A, a plurality of thin film transistors 20 in the region A all have characteristics A, and a plurality of thin film transistors 20 in the region B all have characteristics B. As a result, since the thin film transistors 20 having the characteristics A and the thin film transistors 20 having the characteristics B abut each other on the “linear” boundary between the region A and the region B, differences in display resulting from differences in the characteristics appear as a “line shape.” For that reason, display unevenness on the liquid crystal screen becomes “streaks” and ends up being emphasized.

On the other hand, in FIG. 5B, since the neighboring thin film transistors 20 in the same region (the region A/region B) have different characteristics from each other, differences in display due to differences in characteristics are dispersed and differences in display due to differences in characteristics do not appear as a “line shape.” Therefore, display unevenness on the liquid crystal screen can be reduced.

In the first example, to realize the above, the laser irradiation device 10 makes radiation ranges of the laser beam 14 radiated to the prescribed regions of the amorphous silicon thin films 21 different from each other for each prescribed region.

As a result, in the same region shown in FIG. 5B (for example, in the region A), the radiation ranges of the laser beam 14 radiated to the prescribed regions of the neighboring amorphous silicon thin films 21 become different from each other. That is, at least the prescribed regions of the neighboring amorphous silicon thin films 21 among the plurality of amorphous silicon thin films 21 included in the same region (for example, the region A) are irradiated with the laser beam 14 in different irradiation ranges. As a result, the radiation ranges of the laser beam 14 lastly radiated to the prescribed regions of the neighboring amorphous silicon thin films 21 in the same region (for example, in the region A) are also different from each other. As a result, electron mobilities of neighboring polysilicon thin films 22 in the same region (for example, in the region A) are different from each other.

As described above, in the first example, to make the irradiation ranges of the laser beam 14 different, at least neighboring opening portions among opening portions (transmission regions) of the projection mask pattern 15 provided on the microlens array 13 are formed to have different shapes (or areas) from each other. In other words, shapes (areas, sizes, and/or dimensions) of the neighboring opening portions in the projection mask pattern 15 are configured to be different from each other.

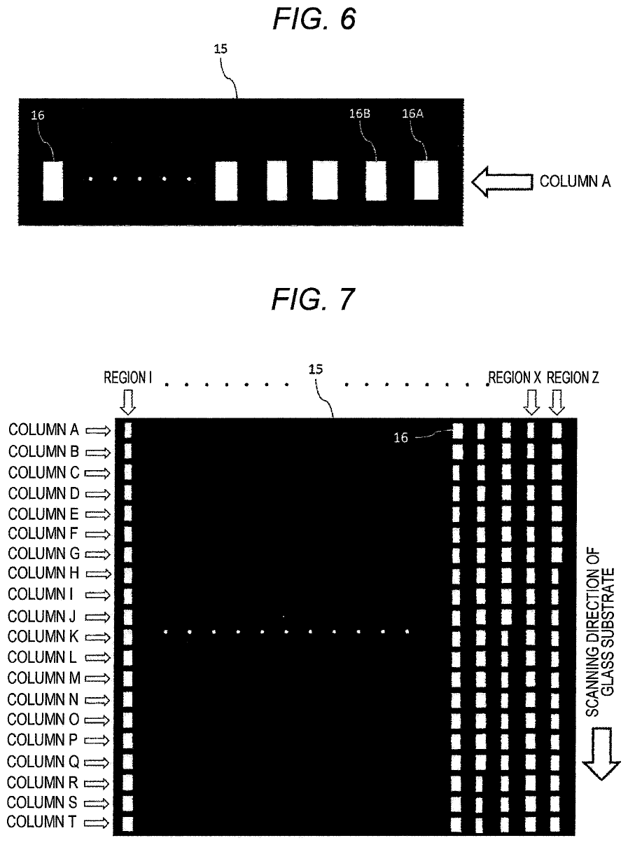

FIG. 6 is a diagram showing configurations of opening portions 16 (transmission regions) of the projection mask pattern 15 in the first example. The opening portions 16 illustrated in FIG. 6 are configurations of opening portions 16 in a region corresponding to a column A of the microlens array 13 illustrated in FIG. 2 in the projection mask pattern 15.

As shown in FIG. 6, the projection mask pattern 15 is provided with the opening portions 16 (transmission regions) through which the laser beam 14 passes. The laser beam 14 passes through the transmission regions 16 and is projected on the prescribed regions of the amorphous silicon thin films 21. In the first example, as illustrated in FIG. 6, the opening portions 16 (transmission regions) adjacent to each other among the opening portions 16 (transmission regions) included in one row of the projection mask pattern 15 are configured to have different shapes (areas, sizes and/or dimensions) from each other. Specifically, as illustrated in FIG. 6, shapes (areas, sizes, and/or dimensions) of an opening portion 16A and an opening portion 16B adjacent to each other are different from each other. Also, the opening portion 16B and an opening portion 16C adjacent to each other also have different shapes (areas, sizes, and/or dimensions). Thus, at least shapes (areas, sizes, and/or dimensions) of neighboring opening portions 16 in one row of the projection mask pattern 15 are different from each other.

Each of the opening portions 16 provided in the projection mask pattern 15 illustrated in FIG. 6 has, for example, a substantially rectangular or trapezoidal shape and a long side thereof is about 100 μm. On the other hand, widths of the opening portions 16 differ at least between neighboring opening portions 16 (for example, the opening portions 16A and 16B) and are, for example, 25 to 50 μm. Also, the shapes, areas, sizes, and/or dimensions of the opening portions 16 of the projection mask pattern 15 are merely examples, and any size may be used as long as it corresponds to that of the microlenses 17. Further, the shapes of the opening portions 16 are also examples, and are not limited to rectangular or trapezoidal shapes but may be any shape.

Also, although long sides of the opening portions 16 are substantially the same in each of the opening portions 16 in the example of FIG. 6, lengths of the long sides may be different from each other. For example, in FIG. 6, the opening portion 16A and the opening portion 16B may differ from each other in the length of opening portion 16.

FIG. 7 is another diagram showing a configuration of the projection mask pattern 15. The projection mask pattern 15 has the opening portions 16 to correspond to respective microlenses 17 included in the microlens array 13 illustrated in FIG. 2. For example, the projection mask pattern 15 is provided with twenty opening portions 16 in one row (that is, a region I or a region X). In addition, as illustrated in FIG. 7, at least opening portions 16 adjacent to each other in one column (for example, a column A or a column B) of the projection mask pattern 15 have different shapes (areas, sizes, and/or dimensions) from each other. For example, shapes (areas, sizes, and/or dimensions) of the opening portions 16 in the region X and the region Z adjacent to each other in the column A are different from each other. Also, shapes (areas, sizes, and/or dimensions) of the opening portions 16 in the region X and the region Z adjacent to each other in the column B are different from each other. In this way, in the projection mask pattern 15, the shapes (areas, sizes, and/or dimensions) of the neighboring opening portions 16 in a direction orthogonal to the scanning direction of the substrate 30 are configured to be different from each other. Also, in the projection mask pattern 15, the shapes (areas, sizes, and/or dimensions) of the neighboring opening portions 16 in a direction parallel to the scanning direction of the substrate 30 (that is, the scanning direction) may be configured to be different from each other.

Further, as illustrated in FIG. 7, shapes (areas, sizes and/or dimensions) of the opening portions 16 in columns adjacent to each other (for example, the column A and the column B in the region I) in one row (for example, the region I in FIG. 7) of the projection mask pattern 15 may be different from each other. For example, shapes (areas, sizes, and/or dimensions) of the opening portions 16 in the columns B and C in the region X may be different from each other.

Further, in one row of the projection mask pattern 15 (the region I or the region X in FIG. 7), a total area of the twenty opening portions 16 is preferably a prescribed value (a prescribed area). That is, the total area of the opening portions 16 in the columns A to T of the region I of the projection mask pattern 15 illustrated in FIG. 7 and the total area of the opening portions 16 in the columns A to T of the region X are all a prescribed value (a prescribed area). As a result, no matter which “row” of the projection mask pattern 15 is used, a total of irradiation areas of the laser beam 14 radiated to the prescribed regions of the amorphous silicon thin films 21 becomes constant. Also, in one row of the projection mask pattern 15 (the region I or the region X in FIG. 7), the total area of the twenty opening portions 16 may not necessarily be a prescribed value (a prescribed area), and the irradiation area of the laser beam 14 may be different for each “row.”

In the example of FIG. 7, the opening portions (transmission regions) 16 of the projection mask pattern 15 is provided to be orthogonal to the movement direction (scanning direction) of the substrate 30. Also, the opening portions (transmission regions) 16 of the projection mask pattern 15 may not necessarily be orthogonal to the movement direction (scanning direction) of the substrate 30 and may be provided parallel (substantially parallel) to the movement direction (scanning direction).

The laser irradiation device 10 irradiates the substrate 30 illustrated in FIG. 4 with the laser beam 14 using the projection mask pattern 15 shown in FIG. 7. As a result, in the substrate 30 illustrated in FIG. 4, for example, the prescribed regions of the amorphous silicon thin films 21 in the region X are irradiated with the laser beam 14 using the twenty microlenses 17 masked by the columns A to T in the region X illustrated in FIG. 7. On the other hand, thin film transistors 20 in the region Z adjacent thereto are irradiated with the laser beam 14 using twenty microlenses 17 masked by the columns A to T in the region X illustrated in FIG. 7. As a result, in regions in the scanning direction (that is, the region I and the region II) on the substrate 30 illustrated in FIG. 4, the prescribed regions of the amorphous silicon thin films 21 in the neighboring regions are irradiated with the laser beam 14 using the microlenses 17 in different columns from each other. For this reason, in the regions in the scanning direction (that is, the region X and the region Z) on the substrate 30 illustrated in FIG. 4, the thin film transistors 20 in the neighboring regions have different characteristics from each other.

Further, as described above, since the laser beam 14 to be radiated is different between the regions (the regions A and B illustrated in FIG. 4) orthogonal to the scanning direction, the thin film transistors 20 in the neighboring regions have different characteristics.

As a result, the neighboring thin film transistors 20 have different characteristics over the entire substrate 30. For that reason, differences in display (for example, a difference in shades of color or the like) due to differences in the characteristics of the thin film transistors 20 are dispersed and do not appear as a line shape. Therefore, display unevenness does not become “streaks” on a liquid crystal screen, and the display unevenness can be prevented from being emphasized.

In the first example, the substrate 30 is moved by a prescribed distance each time the laser beam 14 is radiated using one microlens 17. The prescribed distance is a distance “H” between the plurality of thin film transistors 20 on the substrate 30 as illustrated in FIG. 4. The laser irradiation device 10 stops irradiation of the laser beam 14 while the substrate 30 is moved by the prescribed distance.

After the substrate 30 has moved by the prescribed distance “H,” the laser irradiation device 10 again radiates the laser beam 14 using the microlens 17 included in the microlens array 13. Further, in the first example, since the projection mask pattern 15 shown in FIG. 7 is used, one amorphous silicon thin film 21 is irradiated with the laser beam 14 using the twenty microlenses 17 having different irradiation ranges (areas, sizes and/or dimensions) from each other.

In addition, the polysilicon thin film 22 is formed in the prescribed region of the amorphous silicon thin film 21 on the substrate 30 by using laser annealing, and then in another step, the source 23 and the drain 24 are formed in the thin film transistor 20.

As described above, in the first example, since the characteristics of the thin film transistors 20 adjacent to each other in the entire substrate 30 are different from each other, differences in display (for example, a difference in shades of color or the like) due to differences in the characteristics do not appear as a “line shape.” For that reason, display unevenness does not become “streaks” on a liquid crystal screen, and the display unevenness can be prevented from being emphasized.

### SECOND EXAMPLE

A second configuration is an example of laser annealing performed using one projection lens 18 instead of the microlens array 13.

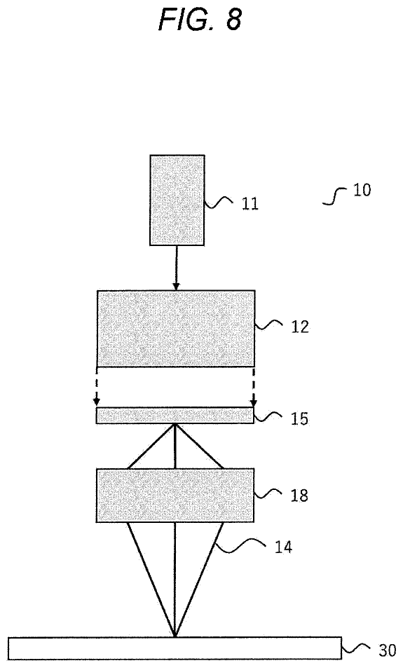

FIG. 8 is a diagram showing a configuration of the laser irradiation device 10 according to a second example. The laser irradiation device 10 according to the second example includes a laser light source 11, a coupling optical system 12, a projection mask pattern 15, and a projection lens 18. Further, since the laser light source 11 and the coupling optical system 12 have the same configuration as the laser light source 11 and the coupling optical system 12 in the first example shown in FIG. 1, a detailed description therefor will be omitted. Also, since the projection mask pattern has the same configuration as the projection mask pattern in the first example, a detailed description therefor will be omitted.

In the second example, the projection mask pattern 15 is, for example, the projection mask pattern 15 illustrated in FIGS. 6 and 7. However, since the mask pattern of the projection mask pattern 15 is converted by a magnification of an optical system of the projection lens 18, it may be different in shape (area, size, and/or dimension) from the projection mask pattern illustrated in FIGS. 6 and 7. The laser beam is transmitted through the opening portions 16 (transmission regions) of the projection mask pattern 15 and is radiated to the prescribed region of the amorphous silicon thin film 21 via the projection lens 18. As a result, the prescribed region of the amorphous silicon thin film 21 is instantaneously heated and melted, and a part of the amorphous silicon thin film 21 becomes the polysilicon thin film 22.

Also, in the second example, the laser irradiation device 10 radiates the laser beam 14 at a prescribed cycle, moves the substrate 30 while the laser beam 14 is not radiated, and irradiates a region of the next amorphous silicon thin film 21 with the laser beam 14. Also in the second example as shown in FIG. 4, the amorphous silicon thin film 21 is disposed on the entire surface of the substrate 30. Then, the laser irradiation device 10 irradiates the prescribed region of the amorphous silicon thin film 21 disposed on the substrate 30 with the laser beam 14 at a prescribed cycle.

When the projection lens 18 is used, the laser beam 14 is converted by the magnification of the optical system of the projection lens 18. That is, a pattern of the projection mask pattern 15 is converted by the magnification of the optical system of the projection lens 18, and the prescribed region of the amorphous silicon thin film 21 formed (deposited) on the substrate 30 is laser-annealed.

That is, the mask pattern of the projection mask pattern 15 is converted by the magnification of the optical system of the projection lens 18, and the prescribed region of the amorphous silicon thin film 21 formed (deposited) on the substrate 30 is laser-annealed. For example, when the magnification of the optical system of the projection lens 18 is about twice, the mask pattern of the projection mask pattern 15 is multiplied by about ½ (0.5), and the prescribed region of the substrate 30 is laser-annealed. Also, the magnification of the optical system of the projection lens 18 is not limited to about twice and may be any magnification. In the mask pattern of the projection mask pattern 15, the prescribed region on the substrate 30 is laser-annealed in accordance with the magnification of the optical system of the projection lens 18. For example, when the magnification of the optical system of the projection lens 18 is four times, the mask pattern of the projection mask pattern 15 is multiplied by about ¼ (0.25), and the prescribed region of the amorphous silicon thin film 21 formed (deposited) on the substrate 30 is laser-annealed.

Further, when the projection lens 18 forms an inverted image, a reduced image of the projection mask pattern 15 projected on the amorphous silicon thin film 21 formed (deposited) on the substrate 30 is a pattern rotated 180 degrees about an optical axis of the projection lens 18. On the other hand, when the projection lens 18 forms an erect image, a reduced image of the projection mask pattern 15 projected on the amorphous silicon thin film 21 formed (deposited) on the substrate 30 remains as it is.

As described above, in the second example, even when laser annealing is performed using one projection lens 18, characteristics of the thin film transistors 20 adjacent to each other are different from each other in the whole substrate 30, whereby a difference in display (for example, a difference in shades of color or the like) due to a difference in the characteristics does not appear in a “line shape.” For that reason, display unevenness does not become a “streak” on a liquid crystal screen, and the display unevenness can be prevented from being emphasized.

Further, in the above description, when there are descriptions such as “vertical,” “parallel,” “plane,” “orthogonal,” and the like, these descriptions do not indicate strict meanings. That is, the terms “vertical,” “parallel,” “plane,” and “orthogonal” allow tolerances and errors in designing, manufacturing, or the like, and mean “substantially vertical,” “substantially parallel,” “substantially plane,” and “substantially orthogonal.” In addition, the tolerances or errors are meant to have units within a range not departing from configurations, operations, and desired effects.

Also, in the above description, when there are descriptions such as dimensions or sizes in appearance being “same,” “equal,” “different,” and the like, these descriptions do not indicate strict meanings. That is, the terms “same,” “equal,” and “different” allow tolerances and errors in designing, manufacturing, or the like, and mean “substantially the same,” “substantially equal,” and “substantially different.” In addition, the tolerances or errors are meant to have units within a range not departing from configurations, operations, and desired effects.

Although this disclosure has been described on the basis of the drawings and examples, it should be noted that those skilled in the art can easily make various changes and modifications on the basis of this disclosure. Therefore, these changes and modifications are included in the scope of this disclosure. For example, functions included in each means, each step, and the like can be rearranged not to be logically inconsistent, and a plurality of means, steps, and the like can be combined into one or can be divided. Also, configurations described in the above examples may be combined as appropriate.

What is claimed is:

1. A laser irradiation device comprising:
a light source that generates a laser beam;
a projection lens that irradiates a prescribed region of an amorphous silicon thin film deposited on a substrate with the laser beam; and
a projection mask pattern disposed on the projection lens and provided with a plurality of opening portions to irradiate the prescribed region of the amorphous silicon thin film with the laser beam,
wherein the projection lens irradiates the prescribed region of the amorphous silicon thin film on the substrate moving in a prescribed direction with the laser beam through the projection mask pattern, and
the projection mask pattern is configured such that areas of at least neighboring opening portions in a column orthogonal to a movement direction are different from each other.

2. The laser irradiation device according to claim 1,
wherein the projection lens is a plurality of microlenses included in a microlens array that can separate the laser beam, and
the projection mask pattern is configured such that the areas of at least the neighboring opening portions among the opening portions corresponding to one column of the microlenses orthogonal to the movement direction are different from each other.

3. The laser irradiation device according to claim 2,
wherein the laser beam radiated from the light source is radiated to the prescribed region of the amorphous silicon thin film through the microlenses corresponding to the one column orthogonal thereto in a single irradiation, and
the projection lens irradiates at least neighboring prescribed regions among prescribed regions of the amorphous silicon thin film included in the column orthogonal to the movement direction with the laser beam in different irradiation ranges.

4. The laser irradiation device according to claim 2, wherein the projection mask pattern is configured such that a total area of the plurality of opening portions corresponding to the microlenses corresponding to one row in the movement direction is set to a prescribed value.

5. The laser irradiation device according to claim 2, wherein the projection mask pattern is configured such that the areas of at least the neighboring opening portions among the opening portions corresponding to one row of the microlenses in the movement direction are different from each other.

6. The laser irradiation device according to claim 1, wherein the projection lens radiates the laser beam to the amorphous silicon thin film attached to a region corresponding to a region between a source electrode and a drain electrode included in a thin film transistor to form a polysilicon thin film.

7. A method of manufacturing a thin film transistor comprising:
a first step of generating a laser beam from a light source;
a second step of irradiating a prescribed region of an amorphous silicon thin film deposited on a substrate with the laser beam using a projection lens provided with a projection mask pattern including a plurality of opening portions; and
a third step of moving the substrate in a prescribed direction each time the laser beam is radiated,
wherein, in the second step, the laser beam is radiated via the projection mask pattern in which areas of at least neighboring opening portions in one column orthogonal to a movement direction are different from each other.

8. The method according to claim 7,
wherein the projection lens is a plurality of microlenses included in a microlens array that can separate the laser beam, and
in the second step, the laser beam is radiated through the projection mask pattern in which the areas of at least the neighboring opening portions corresponding to the microlenses in the one column orthogonal to the movement direction are different from each other.

9. The method according to claim 8,
wherein the laser beam radiated from the light source is radiated to the prescribed region of the amorphous silicon thin film through microlenses corresponding to the one column orthogonal thereto in a single irradiation, and
in the second step, the laser beam is radiated to at least neighboring prescribed regions of the amorphous silicon thin film among prescribed regions of the amorphous silicon thin film included in the column orthogonal to the movement direction with the laser beam in different irradiation ranges.

10. The method according to claim 8, wherein the prescribed region of the amorphous silicon thin film is irradiated with the laser beam via the projection mask pattern in which, in the second step, a total area of the plurality of opening portions corresponding to the microlenses corresponding to one row in the movement direction is set to a prescribed value.

11. The method according to claim 8, wherein the prescribed region of the amorphous silicon thin film is irradiated with the laser beam via the projection mask pattern in which, in the second step, areas of at least neighboring opening portions among the opening portions corresponding to the microlenses in one row in the movement direction are different from each other.

12. The method according to claim 7, wherein, in the second step, the prescribed region of the amorphous silicon thin film deposited on a region corresponding to a region between a source electrode and a drain electrode included in the thin film transistor is irradiated with the laser beam to form a polysilicon thin film.

13. A projection mask disposed on a projection lens that radiates a laser beam generated from a light source,
wherein the projection mask is provided with a plurality of opening portions to irradiate a prescribed region of an amorphous silicon thin film deposited on a substrate moving in a prescribed direction with the laser beam, and
each of the plurality of opening portions is configured such that areas of at least neighboring opening portions in one column orthogonal to the prescribed direction are different from each other.
